(19) United States
(12) Patent Application Publication
(10) Pub. No.: US 2020/0241092 A1
(43) Pub. Date: Jul. 30, 2020

(54) Magnetic Assemblies For Downhole Nuclear Magnetic Resonance (NMR) Tools

(71) Applicant: Halliburton Energy Services, Inc., Houston, TX (US)

(72) Inventors: Rebecca Jachmann, Spring, TX (US); Arcady Reiderman, Katy, TX (US)

(73) Assignee: Halliburton Energy Services, Inc., Houston, TX (US)

(21) Appl. No.: 16/652,930

(22) PCT Filed: Dec. 29, 2017
(86) PCT No.: PCT/US2017/069036

§ 371 Date: Apr. 1, 2020

(51) Int. Cl. G01R 33/38; G01N 24/08; G01R 33/383; G01R 33/3873; G01V 3/32

(52) U.S. Cl. CPC G01R 33/3808; G01N 24/081; G01V 3/32; G01R 33/3873; G01R 33/383

(57) ABSTRACT

Magnetic assemblies for downhole nuclear magnetic resonance tools are provided. A magnetic assembly includes one or more permanent magnets and one or more magnetically permeable structures. The magnetically permeable structures generate an induced magnetic field responsive to the magnetic field of the permanent magnets. The induced magnetic field corrects axial asymmetries in the magnetic field of the permanent magnets. The one or more permanent magnets may be interleaved, in the magnet assembly, with the one or more permanent magnets.

### TECHNICAL FIELD

The present description relates in general to downhole nuclear magnetic resonance (NMR) tools, and more particularly, for example and without limitation, to magnet assemblies for downhole nuclear magnetic resonance (NMR) tools.

### BACKGROUND OF THE DISCLOSURE

In the field of logging (e.g. wireline logging, logging while drilling (LWD) and measurement while drilling (MWD)), nuclear magnetic resonance (NMR) tools have been used to explore the subsurface based on the magnetic interactions with subsurface material. Some downhole NMR tools include a magnet assembly that produces a static magnetic field, and a coil assembly that generates radio frequency (RF) control signals and detects magnetic resonance phenomena in the subsurface material. Properties of the subsurface material can be identified from the detected phenomena.

The description provided in the background section should not be assumed to be prior art merely because it is mentioned in or associated with the background section. The background section may include information that describes one or more aspects of the subject technology.

### BRIEF DESCRIPTION OF THE DRAWINGS

The following figures are included to illustrate certain aspects of the present disclosure, and should not be viewed as exclusive embodiments. The subject matter disclosed is capable of considerable modifications, alterations, combinations, and equivalents in form and function, without departing from the scope of this disclosure.

FIG. 1 is a diagram of an example well system, in accordance with aspects of the subject disclosure.

FIG. 2 is a diagram of an example well system that includes a logging tool in a wireline measurement environment, in accordance with aspects of the subject disclosure.

FIG. 3 is a diagram of an example well system that includes a logging tool in a logging while drilling (LWD) environment, in accordance with aspects of the subject disclosure.

FIG. 4A shows a schematic cross-sectional side view of a portion of an NMR tool having a magnet assembly and an antenna assembly for LWD operations, in accordance with aspects of the subject disclosure.

FIG. 4B shows a schematic cross-sectional top view of an NMR tool having a magnet assembly and an antenna assembly for wireline operations, in accordance with aspects of the subject disclosure.

FIG. 5 is schematic side view of a permanent magnet having an ideal axial magnetization, in accordance with aspects of the subject disclosure.

FIG. 6 is schematic side view of a permanent magnet having a magnetization that deviates from the axial direction, in accordance with aspects of the subject disclosure.

FIG. 7 is a schematic side view of a magnet assembly having a permanent magnet attached to a magnetically permeable structure, in accordance with aspects of the subject disclosure.

FIG. 8 is a schematic side view of the magnet assembly of FIG. 7 showing the transverse components of the magnetization and magnetic fields, in accordance with aspects of the subject disclosure.

FIG. 9 shows a perspective view of a magnet assembly having a permanent magnet having a south pole attached to a magnetically permeable structure, in accordance with aspects of the subject disclosure.

FIG. 10 shows a perspective view of a magnet assembly having a permanent magnet having a north pole attached to a magnetically permeable structure, in accordance with aspects of the subject disclosure.

FIG. 11 shows a perspective view of a magnet assembly having an arrangement of permanent magnets interleaved with an arrangement of magnetically permeable structures, in accordance with aspects of the subject disclosure.

FIG. 12 shows a perspective view of another magnet assembly having an arrangement of permanent magnets interleaved with an arrangement of magnetically permeable structures, in accordance with aspects of the subject disclosure.

FIG. 13 shows a cross-sectional side view of a portion of a magnet assembly having an arrangement of permanent magnets interleaved with an arrangement of magnetically permeable structures, in accordance with aspects of the subject disclosure.

FIG. 14 shows a schematic cross-sectional top view of an NMR tool having a magnet assembly and an antenna assembly for wireline operations, in accordance with aspects of the subject disclosure.

### DETAILED DESCRIPTION

The detailed description set forth below is intended as a description of various implementations and is not intended to represent the only implementations in which the subject technology may be practiced. As those skilled in the art would realize, the described implementations may be modified in various different ways, all without departing from the scope of the present disclosure. Accordingly, the drawings and description are to be regarded as illustrative in nature and not restrictive.

Oil field operations can be improved using information regarding the parameters and conditions encountered downhole. Such information typically includes characteristics of the earth formations traversed by the borehole, and the process of collecting such information is commonly referred to as “logging”. Logging can be performed by several methods including wireline logging, tubing-conveyed logging, and “logging while drilling” (LWD).

In wireline logging, a sonde is lowered into the borehole after some or all of the well has been drilled. The sonde hangs at the end of a long cable or “wireline” that provides mechanical support to the sonde and also provides an electrical connection between the sonde and electrical equipment located at the surface of the well. Various parameters of the earth's formations are measured and correlated with the position of the sonde in the borehole as the sonde is pulled uphole.

Tubing-conveyed logging is similar to wireline logging, but the sonde is mounted on the end of a tubing string. The rigid nature of the tubing string enables the tubing-conveyed sonde to travel where it would be difficult to send a wireline sonde (e.g., along horizontal or upwardly-inclined sections of the borehole). The tubing string can include embedded conductors in the tubing wall for transporting power and telemetry, or a wireline cable can be fed through the interior of the tubing string, or the sonde can simply store data in memory for later retrieval when the sonde returns to the surface.

In LWD, the drilling assembly includes sensing instruments that measure various parameters as the formation is being drilled. LWD enables measurements of the formation while it is less affected by fluid invasion. While LWD measurements are desirable, drilling operations create an environment that is generally hostile to electronic instrumentation, telemetry, and sensor operations.

One of the instruments that can be operated in each of these environments is a nuclear magnetic resonance (NMR) logging tool.

NMR tools employ an arrangement of permanent magnets to establish a strong magnetic field in some designated sensing volume in a subterranean formation. For downhole logging, the permanent magnets are arranged to create a strong magnetic field and have minimal change in elevated temperatures. Variations of the magnetic field strength will depend on the material used to create the field. A field that is substantially temperature independent and resistant to magnetic losses is desired, however, so is a strong field. In many applications, a Samarium Cobalt (e.g., Sm₂Co₁₇) based magnet is used. However, in some implementations, the Samarium cobalt can be mixed with a varying amount of magnetic materials in order to reduce the temperature dependence, taking care to avoid overly reducing the remnant field. In general, the acceptable range of temperature dependence for a permanent magnet for downhole use is about 4%/100C. change.

Symmetric magnetic fields generated by magnets with a known magnetization are often desirable for downhole NMR operations. In one example, an axially symmetric magnetic field (e.g., symmetric about the longitudinal axis of the tool) can be desirable for LWD operations. However, it can be difficult to form permanent magnets and/or assemblies of permanent magnets without deviations from axial symmetry.

In accordance with various aspects of the subject disclosure, magnet assemblies for downhole NMR tools are provided that include permanent magnets and magnetically permeable structures that correct for deviations in the field orientations of the permanent magnets. The magnetically permeable structures may be interleaved with permanent magnets in various arrangements as described in further detail hereinafter.

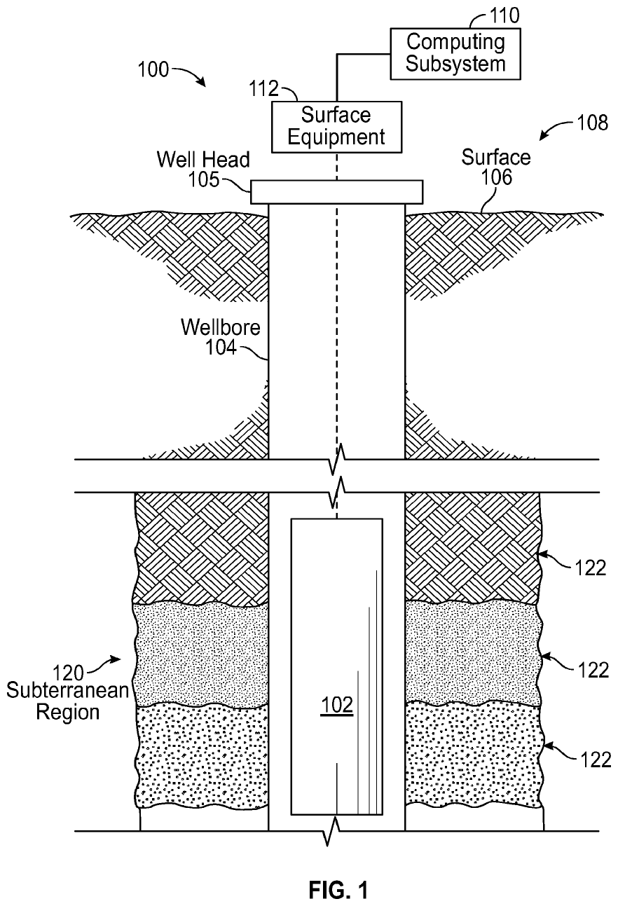

FIG. 1 is a diagram of an example well system 100 that may include a NMR downhole tool with a magnet assembly having permeable structures for field orientation correction. The example well system 100 includes NMR logging system 108 and a subterranean region 120 beneath the ground surface 106. A well system can include additional or different features that are not shown in FIG. 1. For example, the well system 100 may include additional drilling system components, wireline measurement system components, etc.

The subterranean region 120 can include all or part of one or more subterranean formations or zones. The example subterranean region 120 shown in FIG. 1 includes multiple subsurface layers 122 and a wellbore 104 penetrated through the subsurface layers 122. The subsurface layers 122 can include sedimentary layers, rock layers, sand layers, or combinations of these and other types of subsurface layers. One or more of the subsurface layers can contain fluids, such as brine, oil, gas, etc. Although the example wellbore 104 shown in FIG. 1 is a vertical wellbore, the measurement system 108 can be implemented in other wellbore orientations. For example, the measurement system 108 may be adapted for horizontal wellbores, slanted wellbores, curved wellbores, vertical wellbores, or combinations of these.

The example NMR logging system 108 includes a logging tool 102, surface equipment 112, and a computing subsystem 110. In the example shown in FIG. 1, the logging tool 102 is a downhole measurement tool that operates while disposed in the wellbore 104. The example surface equipment 112 shown in FIG. 1 operates at or above the surface 106, for example, near the well head 105, to control the logging tool 102 and possibly other downhole equipment or other components of the well system 100. The example computing subsystem 110 can receive and analyze logging data from the logging tool 102. An NMR logging system can include additional or different features, and the features of an NMR logging system can be arranged and operated as represented in FIG. 1 or in another manner. In some instances, all or part of the computing subsystem 110 can be implemented as a component of, or can be integrated with one or more components of, the surface equipment 112, the logging tool 102 or both. In some cases, the computing subsystem 110 can be implemented as one or more computing structures separate from the surface equipment 112 and the logging tool 102.

In some implementations, the computing subsystem 110 is embedded in the logging tool 102, and the computing subsystem 110 and the logging tool 102 can operate concurrently while disposed in the wellbore 104. For example, although the computing subsystem 110 is shown above the surface 106 in the example shown in FIG. 1, all or part of the computing subsystem 110 may reside below the surface 106, for example, at or near the location of the logging tool 102.

The well system 100 can include communication or telemetry equipment that allows communication among the computing subsystem 110, the logging tool 102, and other components of the NMR logging system 108. For example, the components of the NMR logging system 108 can each include one or more transceivers or similar apparatus for wired or wireless data communication among the various components. For example, the NMR logging system 108 can include systems and apparatus for optical telemetry, wireline telemetry, wired pipe telemetry, mud pulse telemetry, acoustic telemetry, electromagnetic telemetry, or a combination of these and other types of telemetry. In some cases, the NMR logging tool 102 receives commands, status signals, or other types of information from the computing subsystem 110 or another source. In some cases, the computing subsystem 110 receives measurement data, status signals, or other types of information from the logging tool 102 or another source.

NMR logging operations can be performed in connection with various types of downhole operations at various stages in the lifetime of a well system. Structural attributes and components of the surface equipment 112 and logging tool 102 can be adapted for various types of logging operations. For example, NMR logging may be performed during drilling operations, during wireline logging operations, or in other contexts. As such, the surface equipment 112 and the logging tool 102 may include, or may operate in connection with drilling equipment, wireline logging equipment, or other equipment for other types of operations. Logging tool 102 may be a side-looking tool and/or may provide measurements in other directions (e.g., as provided by the MRIL®-Prime tool available from Halliburton of Houston, Tex.).

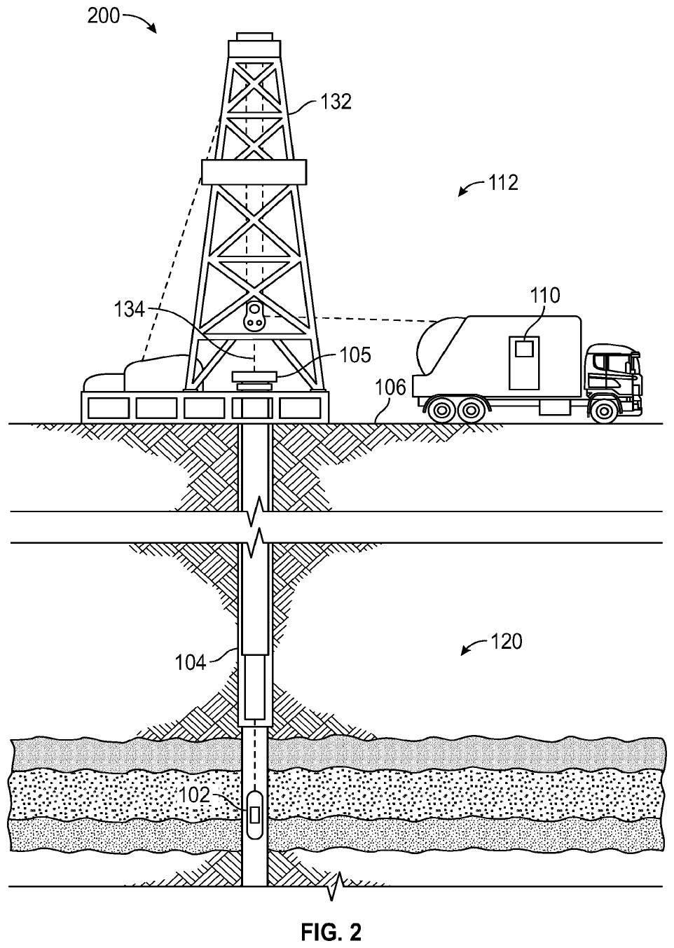

In some examples, NMR logging operations are performed during wireline logging operations. FIG. 2 shows an example well system 200 that includes the NMR logging tool 102 in a wireline logging environment. In some example wireline logging operations, the surface equipment 112 includes a platform above the surface 106 equipped with a derrick 132 that supports a wireline cable 134 that extends into the wellbore 104. Wireline logging operations can be performed, for example, after a drill string is removed from the wellbore 104, to allow the wireline logging tool 102 to be lowered by wireline or measurement cable into the wellbore 104.

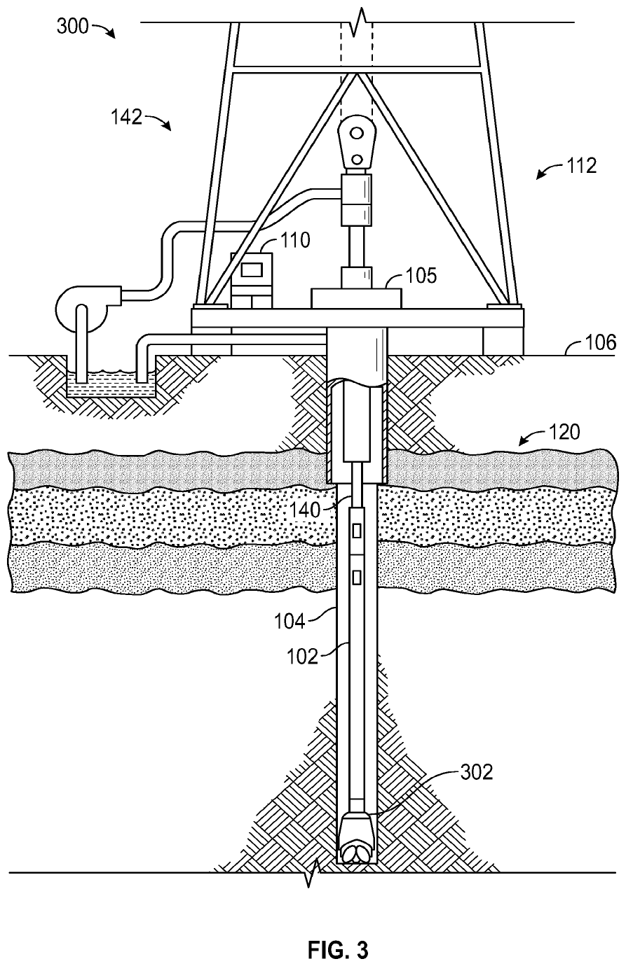

In some examples, logging operations are performed during drilling operations. FIG. 3 shows an example well system 300 that includes the logging tool 102 in a logging while drilling (MWD) environment. Drilling is commonly carried out using a string of drill pipes connected together to form a drill string 140 that is lowered through a rotary table into the wellbore 104. In some cases, a drilling rig 142 at the surface 106 supports the drill string 140, as the drill string 140 is operated to drill a wellbore penetrating the subterranean region 120. The drill string 140 may include, for example, a kelly, drill pipe, a bottomhole assembly, and other components. The bottomhole assembly on the drill string may include drill collars, drill bits, the logging tool 102, and other components. The logging tools may include measuring while drilling (MWD) tools, logging while drilling (LWD) tools, and others.

Logging tool 102 includes an NMR tool for obtaining NMR measurements from subterranean region 120. As shown, for example, in FIG. 2, logging tool 102 can be suspended in the wellbore 104 by a coiled tubing, wireline cable, or another structure that connects the tool to a surface control unit or other components of the surface equipment 112. In some example implementations, logging tool 102 is lowered to the bottom of a region of interest and subsequently pulled upward (e.g., at a substantially constant speed) through the region of interest. As shown, for example, in FIG. 3, logging tool 102 can be deployed in wellbore 104 on jointed drill pipe, hard-wired drill pipe, or other deployment hardware. In some example implementations, logging tool 102 collects data during drilling operations as it moves downward through the region of interest. In some example implementations, logging tool 102 collects data while drill string 140 is moving (e.g., while drill string 140 is being tripped in or tripped out of wellbore 104).

In some scenarios, logging tool 102 collects data at discrete logging points in wellbore 104. For example, logging tool 102 can move upward or downward incrementally to each logging point at a series of depths in wellbore 104. At each logging point, instruments in logging tool 102 obtain measurements associated with subterranean region 120. The measurement data can be communicated to computing subsystem 110 for storage, processing, and analysis. Such data may be gathered and analyzed during drilling operations (e.g., during logging while drilling (LWD) operations), during wireline logging operations, or during other types of activities.

Computing subsystem 110 can receive and analyze the logging data from logging tool 102 to detect properties of various subsurface layers 122. For example, computing subsystem 110 can identify the density, viscosity, porosity, material content, or other properties of subsurface layers 122 based on the NMR measurements acquired by logging tool 102 in wellbore 104.

Logging tool 102 obtains NMR signals by polarizing nuclear spins in subterranean region 120 with the magnet assembly and pulsing the nuclei with a radio frequency (RF) magnetic field generated by the antenna assembly. Various pulse sequences (e.g., series of radio frequency pulses, delays, and other operations) can be applied to obtain NMR signals, including the Carr Purcell Meiboom Gill (CPMG) sequence (in which the spins are first tipped using a tipping pulse followed by a series of refocusing pulses), the Optimized Refocusing Pulse Sequence (ORPS) in which the refocusing pulses are less than 180°, a saturation recovery pulse sequence, and/or other pulse sequences.

The acquired spin-echo signals (or other NMR data) may be processed (e.g., inverted, transformed, etc.) to a relaxation-time distribution (e.g., a distribution of transverse relaxation times or a distribution of longitudinal relaxation times, or both). The relaxation-time distribution can be used to determine various physical properties of the formation by solving one or more inverse problems. In some cases, relaxation-time distributions are acquired for multiple logging points and used to train a model of the subterranean region. In some cases, relaxation-time distributions are acquired for multiple logging points and used to predict properties of the subterranean region.

In the example of FIG. 3, NMR logging tool 102 is integrated into the bottom-hole assembly near bit 302. NMR logging tool 102 may take the form of a drill collar, i.e., a thick-walled tubular that provides weight and rigidity to aid the drilling process. As the bit extends the borehole through the formations, the NMR logging tool collects measurements relating to spin relaxation time distributions as a function of depth or position in the borehole. Other tools and sensors can also be included in the bottomhole assembly to gather measurements of various drilling parameters such as position, orientation, weight-on-bit, borehole diameter, etc. Tool 102 may also include a control and/or telemetry module that collects data from various bottomhole assembly instruments (including position and orientation information) and stores them in internal memory. Selected portions of the data can be communicated to surface receivers by, e.g., mud pulse telemetry. Other logging-while drilling telemetry methods also exist and could be employed. For example, electromagnetic telemetry or through-wall acoustic telemetry can be employed with an optional repeater in the drill string to extend the telemetry range. Most telemetry systems also enable commands to be communicated from the surface to the control and telemetry module to configure the operation of the tools.

At various times during the drilling process, the drill string may be removed from the borehole. Once the drill string has been removed, logging operations can be conducted using a wireline logging tool (e.g., a sensing instrument sonde suspended by a cable having conductors for transporting power to the tool and telemetry from the tool to the surface) as described above in connection with FIG. 2. The wireline logging tool 102 of FIG. 2 may have pads and/or centralizing springs to maintain the tool near the axis of the borehole as the tool is pulled uphole.

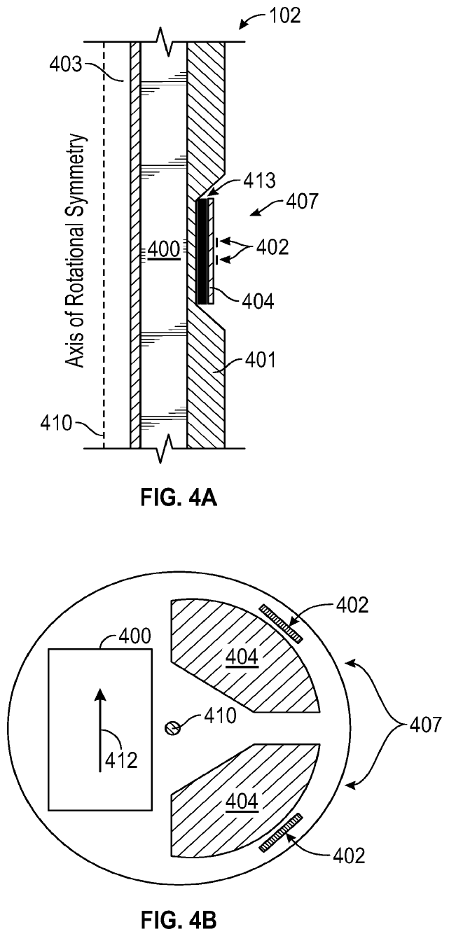

FIGS. 4A and 4B respectively show exemplary implementations of an NMR logging 102 for LWD and wireline operations. In the example of FIG. 4A, only a portion of the tool is shown, for clarity. In particular, one side of a cross-sectional view of tool 102 is shown in an implementation in which the tool is symmetric about an axis of symmetry 410 (e.g., corresponding to the longitudinal axis of tool 102). A full picture of tool 102 of FIG. 4A can be envisaged by rotating the structures shown in FIG. 4A, 360 degrees around axis 410.

In each of the examples of FIGS. 4A and 4B, tool 102 includes magnet assembly 400. Magnet assembly 400 includes an arrangement of permanent magnets to provide a desired static magnetic field. In each of the examples of FIGS. 4A and 4B, tool 102 also includes one or more antenna assemblies 407 including one or more antenna(s) such as antennas 402. Antennas 402 may include coaxial, solenoidal, frame, or any other kind of antenna in any desired number to induce, in region 120, magnetic fields that are, for example, primarily perpendicular to the static magnetic field of magnet assembly 400. As discussed in further detail hereinafter, magnet assembly 400 in each of the examples of FIGS. 4A and 4B also includes magnetically permeable structures. The magnetically permeable structures in magnet assembly 400 help maintain the desired direction of magnetization and/or the symmetry of the magnetic field of the magnet assembly.

As shown in each of the examples of FIGS. 4A and 4B, additional permeable materials 404 may be included in tool 102 to enhance sensitivity of the antennas and/or to favorably shape antenna field lines. Additional permeable materials 404 may be positioned directly underneath the antenna as shown. Additional permeable materials 404 are macroscopically non-conductive and may have a saturation level above 0.4 Tesla. The non-conductive additional permeable materials 404 can help to boost the antenna efficiency and shield a conductive magnet from the RF magnetic field of the antenna. Additional permeable materials 404 can be radially different (e.g., having a different radial width and/or position, different inner diameter and/or different outer diameter) from the permeable material included in the magnet assembly. Additional permeable materials 404 can have a different permeability from that of the permeable material included in the magnet assembly.

In the example of FIG. 4A, tool 102, configured for a LWD operation, includes magnet assembly 400 disposed between mud channel 403 and collar 401. Antenna assembly 407 is disposed radially outward of magnet assembly 400 (e.g., in a recess in collar 401) and may include one or more layers 413 of material (e.g., copper mesh, acoustic dampeners, adhesive, etc.) between additional permeable material 404 and antenna 402. In the example of FIG. 4A, additional permeable material 404 is separated from magnet assembly 400 by a portion of collar 401. In the example of FIG. 4A, the magnetization direction of magnet assembly 400 may be aligned with axis 410 of tool 102.

In the example of FIG. 4B, a cross-sectional view of tool 102 in a plane perpendicular to axis 410 is shown. In the example of FIG. 4B, magnet assembly 400 has a magnetization direction 412 that is directed toward an edge of tool 102 rather than along or parallel to axis 410 of tool 102. A magnetization direction 412 that is directed toward the edge (e.g., the front or side) of the tool can be beneficial in wireline logging operations. In the example of FIG. 4B, additional permeable materials 404 for antennas 402 are free of surrounding and/or adjacent permanent magnets.

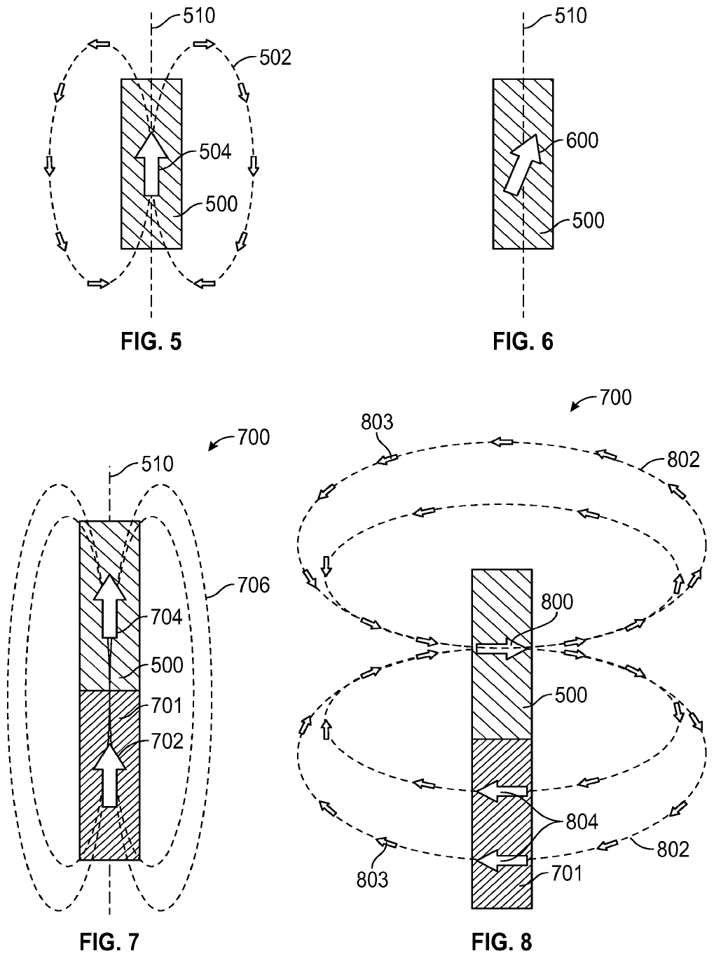

FIG. 5 shows an example of a permanent magnet 500 that may be included in magnet assembly 400 of either of FIGS. 4A or 4B. In the example of FIG. 5, permanent magnet 500 is shown as generating an ideal magnetic field 502 based on an ideal magnetization direction 504. In the example of FIG. 5, magnet 500 is shown as an elongate structure with a longitudinal axis 510 and with a magnetization direction 504 that is aligned with longitudinal axis 510 of the magnet. In other examples, magnet 500 can be a planar structure with a magnetization that is ideally aligned perpendicular to the planar dimension of the magnet. Axis 510 can be aligned with longitudinal axis 410 of tool 102 or in another direction such as direction 412 as illustrated in FIG. 4B. However, permanent magnets often include imperfections that can cause deviations from the desired magnetic field direction and symmetry.

For downhole operations, the materials of choice for permanent magnet 500 are limited due to either the conductivity of the magnets or temperature stability. One suitable material that can be used for magnet 500 is Sm₂Co₁₇.

With any of these materials and/or structural shapes, during manufacturing, the direction of magnetization may not be set perfectly in the desired direction. For example, permanent magnets are often manufactured from a loose powder. The loose powder is ground into fine particles, which are then pressed and sintered in the presence of a magnetic field. A molding or machining process determines the final shape of the magnets. Different parts of the same magnet can thus have differing localized magnetizations pointing a few degrees off from other parts of the magnet. These local differences can cause the overall field of the permanent magnet to deviate by as much as, for example, two degrees from the desired field orientation.

FIG. 6 shows how magnet 500 may have a magnetization direction 600 that deviates from the desired alignment (e.g., an axial alignment in the example of FIGS. 5 and 6). The deviation in magnetization direction 600 may stem from various possible causes noted above, including uneven cooling and machining tolerances. The deviation in magnetization direction 600 can lead to radial and axial asymmetry of the overall magnetic field of magnet 500 and/or deviations from the desired orientation of the magnetic field, even when axial symmetry is of less importance (e.g., in wireline tools such as tool 102 in the example of FIG. 4B).

In magnetic resonance tools it can be difficult to obtain NMR measurements with high signal-to-noise ratio (SNR) as the NMR signal is based on the natural polarization of the spins. In other words, NMR is naturally a low signal measurement. In downhole logging, other factors come into play. For example, because NMR logging tools are outward-looking, exsitu, tools instead of inward-looking, insitu, tools, the excitation field for generating the measured signal naturally falls off in strength with distance from the tool. For a drilling tool in particular, radial symmetry of the magnetic field is of interest. For a wireline tool, axial length and having a long volume can be important for quick movement, while axial symmetry may be less important.

More specifically, since NMR logging tools include permanent magnets and are looking outside of the tool, the magnetic field created is always a gradient field. The frequency and bandwidth of the excitation and refocusing pulses determines the overall volume of the sensitive region or zone of interest. The space from center frequency −½ band width to center frequency +½ bandwidth is a good approximation of the spatial zone in which the SNR signal will be excited and then received from.

Magnet assemblies for downhole NMR tools are arranged to generate a volume in which the gradient, and shape of that volume is best suited for particular applications. For example, for drilling tools, a thick volume radially (e.g., a low radial gradient field) is desired to minimize transversal vibration effects. A radially thick volume is often provided in a volume design that is relatively short. In a wireline application, however, a long field with higher gradient is desired. The longer field allows faster pulling rates and the large gradient gives way to diffusion measurements.

In accordance with various aspects of the subject disclosure, magnet assemblies for NMR tools are provided that include magnetically permeable structures which straighten out the field axially and bring the roundness and/or straightness back to the field, even for asymmetric permanent magnet fields, which can be beneficial particularly for downhole NMR measurements.

FIG. 7 shows an example of a magnet assembly 700 that includes permanent magnet 500 and magnetically permeable structure 701. Magnet assembly 700 may be an implementation of magnet assembly 400 of FIG. 4. Magnetically permeable structure 701 may have a relative magnetic permeability (e.g., relative to the permeability of free space μ₀=4π×10⁻⁷ Hm⁻¹) of, for example, between 10 and 80,000. Magnetically permeable structure 701 may have a magnetic saturation level above, for example, 1 Tesla. For example, magnetically permeable structure 701 may be formed from low-carbon steel (e.g., steel containing between 0.05% and 0.25% carbon), mu-metal, nanocrystalline alloys, and/or other high permeability materials.

Magnetically permeable structure 701 will have a magnetization induced therein by an external magnetic field. The direction and magnitude of the induced magnetization in magnetically permeable structure 701 depends on the magnetic field produced at the location of magnetically permeable structure 701. Inclusion of magnetically permeable structure 701 in the magnet assembly for tool 102 may have two benefits. The first benefit is that the permeable material is cheaper than the magnetic material, which means the overall cost of the magnet assembly and the tool are reduced in comparison with a magnet-only assembly. The second benefit of including magnetically permeable structure 701 is that the imperfections in the manufactured direction of the permanent magnets can be corrected. Magnetically permeable structure 701 may be macroscopically conductive or non-conductive.

The correction provided by the inclusion of magnetically permeable structure 701 can be illustrated by breaking the direction of a non-perfect magnet into its components, as shown in FIGS. 7 and 8.

As shown in FIG .7, the axial component 704 of the magnetization of magnet 500 generates an axially symmetric magnetic field 706 that causes an axial magnetization 702 in permeable structure 701. Axial magnetization 702 in structure 701 generates an induced magnetic field in the same direction as field 706 of permanent magnet 500, thus enhancing the axially symmetric component of the field.

As FIG. 8 shows, the undesired magnetization component 800 in magnet 500 creates an opposing field in the permeable material. In particular, permeable structure 701 compensates for non-ideal direction 600 of magnetization of permanent magnet 500 by generating an induced magnetic field by a magnetization component 804 that is opposite in direction to the perpendicular component 800 of the magnetization of permanent magnet 500.

In FIG. 8, arrows 803 indicate the direction of magnetic field 802 being created by magnet 500. Within permeable structure 701, an induced magnetization 804 is generated by field 802. As shown, the induced magnetization 804 in permeable structure 701 is generated in an opposite direction to magnetization 800 of magnet 500. Accordingly, permeable structure 701 generates its own field magnetic field based on magnetization 804. Two opposing magnetic fields are thus created at the zone of interest such that no substantial undesired field is created in the zone of interest by magnet assembly 700. The effect of the undesired component of magnet 500 is thus reduced or eliminated. In this way, the undesired component of the permanent magnet's magnetic field is cancelled, and the remaining field is the desired (axially symmetric in this example) field 706.

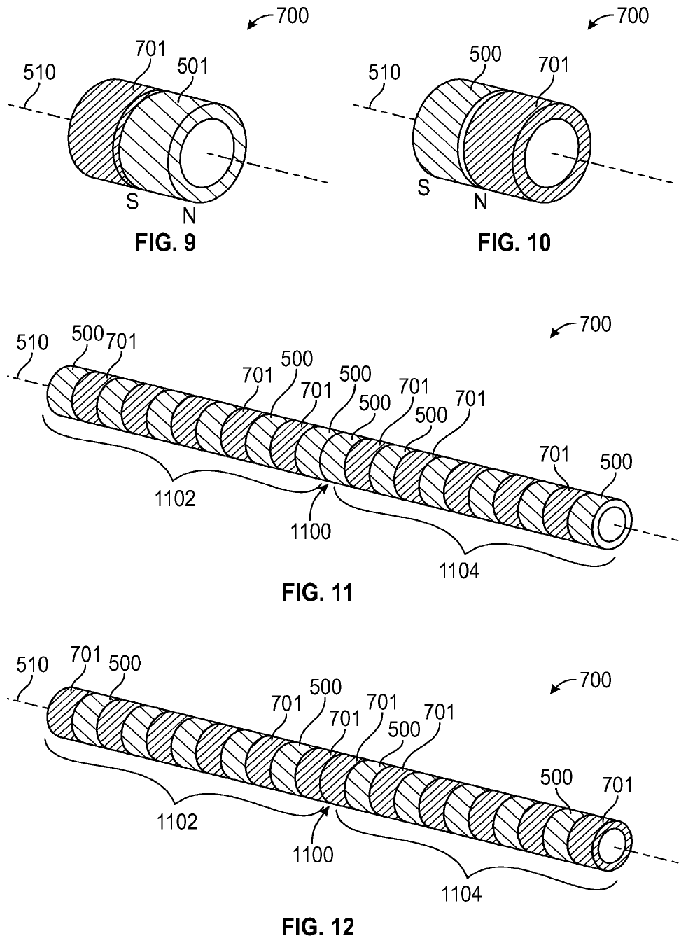

Permanent magnets 500 and/or permeable structures 701 for tool 102 can have any suitable shape. For simplicity, cylindrical permanent magnets and cylindrical permeable structures, each with openings in the center of the cylinder are discussed herein as an example. A cylindrical implementation of permanent magnet 500 and permeable structure 701 is shown in FIG. 9. The cylindrical shape of magnet 500 and permeable structure 701 in FIG. 9 can facilitate inclusion in drilling tools (e.g., by sliding the cylindrical opening therein onto a carrying tube). However, it should be appreciated that the field-correction of permeable materials disclosed herein can apply to other shapes for magnets 500 and permeable structure 701 such as planar shapes for a wireline tool such as tool 102 of the example of FIG. 4B.

In the example of FIG. 9, permeable structure 701 is a cylindrical structure that is axially aligned with cylindrical magnet 500 and attached to the south pole of the magnet. FIG. 10 shows another example of magnet assembly 700 in which a single cylindrical magnet 500 and a single cylindrical permeable structure 701 are provided, with the permeable structure attached to the north pole of the magnet.

In the examples of FIGS. 9 and 10 in which magnet 500 is a cylindrical ring, magnet 500 itself, or a portion of a magnet assembly, can include two or more rings stacked together to increase the axial length and/or strength of the magnet and/or magnet assembly. In various implementations, a cylindrical ring magnet may be a monolithic ring or can be formed from several arcs attached together (e.g., using adhesive) to form the complete ring.

Likewise, permeable structure 701 implemented as a ring may be a monolithic ring or can be formed from several arcs attached together (e.g., using adhesive) to form the complete ring. One or more ring-shaped permeable structures 701 can also be stacked together axially. Multi-piece magnets and/or multi-piece permeable structures can include pieces combined to form odd (e.g., neither round nor square) structural shapes, if desired.

In the example of FIGS. 7-10, a single permanent magnet 500 and a single permeable structure 701 are shown. However, magnet assembly 700 may include multiple permanent magnets and multiple permeable structures. The permeable structures may be interleaved with the permanent magnets in various configurations.

The induced field generated by each permeable structure depends on the distance between that structure and the nearest magnet(s). Accordingly, interleaving or otherwise disbursing permeable structures and/or materials among magnetic structures helps maintain the effectiveness of the permeable materials (e.g., in contrast with a long segment of magnet(s) “capped” by a long segment of permeable material).

In general, magnet assembly 700 may include distributed permeable structures such as structure 701 such that a substantial amount of magnetically permeable material, preferably with a high saturation level, is included as part of the magnet assembly for downhole nuclear magnetic resonance measurements. The distributed permeable structures 701 compensate for the non-ideal direction of magnetization of the various magnets in the magnet assembly, the non-ideality being an attribute of magnet manufacturing. The distributed permeable structures can be alternatingly provided with permanent magnets axially along the tool, radially around the tool, or a combination of alternating axial and radial arrangements.

FIG. 11 shows one example of magnet assembly 700 in an implementation in which distributed permeable structures 701 are alternatingly provided (e.g., interleaved) with permanent magnets 500 axially along the tool or magnet assembly. In the example of FIG. 11, each magnet 500 (which may be monolithic or composed of multiple magnet sections such as rings or arcs as discussed herein) is accompanied by at least one permeable structure 701. Magnets 500 and permeable structure 701 are alternatingly provided in the axial direction in a pattern that is reflected across a center 1100 of the pattern. In the example of FIG. 11, magnet assembly 700 includes two groups 1102 and 1104 that have a common pattern of alternating magnets 500 and permeable structures 701 extending from center 1100 such that group 1102 is an axial reflection of group 1104 across center 1100.

Magnets 500 may be attached directly to adjacent permeable structures 701 or may be separated by a gap (e.g., a non-magnetic zone) from one or more adjacent permeable structures 701. In the example of FIG. 11, the centermost element in each of groups 1102 and 1104 is a magnet 500. However, as shown in FIG. 12, in other examples, the centermost element in each of groups 1102 and 1104 is one of permeable structures 701. In either of the examples of FIGS. 11 and 12, the centermost elements may be disposed in contact with each other at center 1100 or may be equidistantly spaced from center 1100 with a gap therebetween. In another example, a single magnet 500 or a single permeable structure 701 may be centered at center 1100 and for a portion of both groups 1102 and 1104.

FIG. 11 shows an example in which each of groups 1102 and 1104 includes six magnets 500 and five intervening magnetically permeable structures 701. FIG. 12 shows an example in which each of groups 1102 and 1104 includes six magnetically permeable structures 701 and five intervening magnets 500. However, it should be appreciated that the number and distribution of each of magnets 500 and permeable structures 701 can be adjusted to generate the desired symmetric magnetic field.

NMR tool 102 may include one or more magnet assemblies 700 such as one or more of magnet assemblies 700 of FIGS. 11 and/or 12, to generate the desired magnetic field at desired locations along the tool. In one example, three magnet assemblies 700 are provided in an arrangement in which the axially outer two assemblies are oriented (e.g., north-south) in the same direction, with the middle assembly oriented in the opposite axial direction.

In the examples of FIGS. 11 and 12, each of magnets 500 is the same size as the other magnets 500, each of permeable structures 701 is the same size as the other permeable structures 701, and magnets 500 and permeable structures 701 have the same size. However, it should be appreciated that, within a magnet assembly and/or between magnet assemblies, the size and shape of each magnet 500 and each permeable structure 701 can vary relative to other magnets 500 and permeable structures 701. As examples, cylindrical magnets 500 and permeable structures 701 as described herein can vary in radial and axial width within a magnet assembly 700. Permeable structures 701 in a magnet assembly can have a common permeability or can have various different permeabilities.

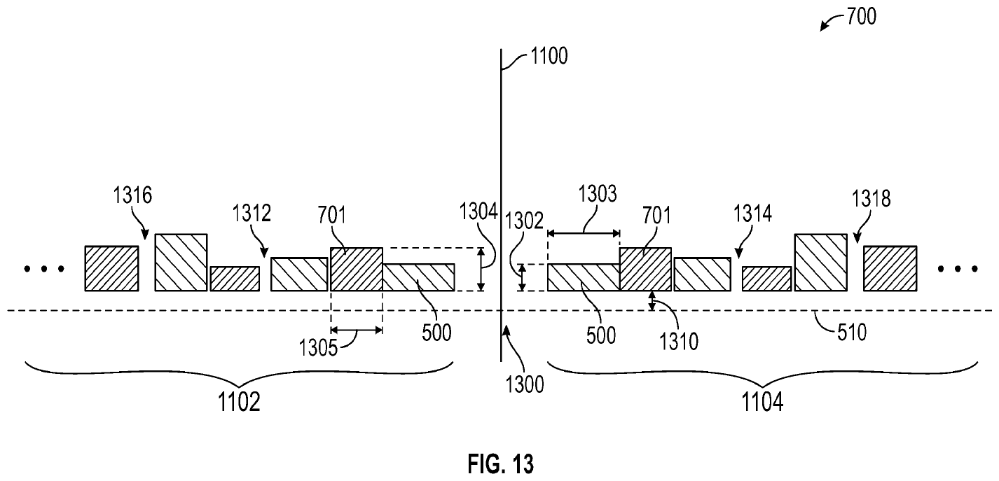

FIG. 13 shows a cross-sectional view of half of a magnet assembly 700 taken along the longitudinal axis 510 of the assembly. Longitudinal axis 510 of FIG. 13 can correspond to axis 410 of tool 102 as shown in FIG. 4A or axis 510 can be otherwise aligned in tool 102. A complete view of assembly 700 of FIG. 13 can be envisaged by a 360 degree rotation of the portion of assembly 700 as shown, about axis 510. As shown, each cylindrical magnet 500 and cylindrical permeable structure 701 has an inner radius 1310 and an outer radius equal to the inner radius 1310 plus the radial width (e.g., radial width 1302 for magnets 500 or radial width 1304 for permeable structures 701). However, it should be appreciated that the inner radius of any of magnets 500 and/or structures 701 can be different (e.g., pairs of magnets 500 and/or pairs of structures 701 spaced apart equidistant from center 1100 and having a common inner radius (or diameter) within the pair can have different inner radii than that of other pairs).

As shown in FIG. 13, magnets 500 have varying radial widths 1302 (e.g., formed from varying inner and/or outer diameters) and varying axial widths 1303 are included in each of groups 1102 and 1104 of assembly 700 such that the varying widths are reflected about center 1100. Permeable structures 701 are provided with varying radial widths 1304 (e.g., formed from varying inner and/or outer diameters) and varying axial widths 1305 in each of groups 1102 and 1104 of assembly 700 such that the varying widths are reflected about center 1100.

FIG. 13 also shows how one or more gaps or non-magnetic zones may be formed at various locations between elements of a magnet assembly 700. In particular, FIG. 13 shows a first pair of gaps 1312 and 1314 and a second pair of gaps 1316 and 1318, each pair being spaced apart equidistant from center 1100. In the example of FIG. 13, a center gap 1300 is also provided between the centermost elements of each of groups 1102. More or fewer gaps than those shown in FIG. 13 can be provided. In some magnet assemblies, the centermost elements of groups 1102 and 1104 are formed in contact (e.g., attached using adhesive). The direction of the magnetization of groups 1102 and 1104 may or may not be reflected about center 1100 (e.g., may be parallel or antiparallel).

As shown in FIGS. 11-13, pairs of permanent magnets 500 and pairs of permeable structures 701 are provided with one of each pair in group 1102 and the other of each pair in group 1104, such that group 1102 is a reflection of group 1104 across center of reflection 1100.

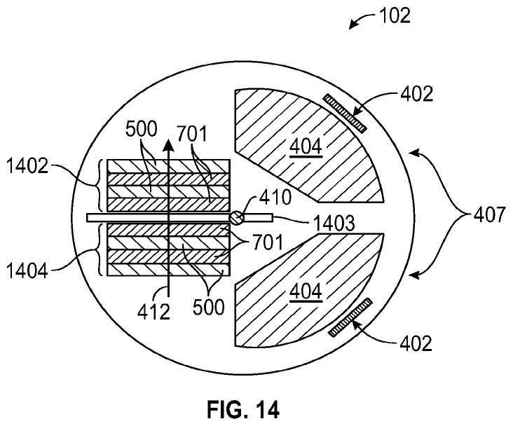

As noted above, the cylindrical implementation and axial orientation/symmetry of magnets 500 and permeable structures 701 described in connection with FIGS. 9-13 can be particularly beneficial in LWD drilling tools such as tool 102 of FIG. 4A above. However, in other implementations, such as for wireline tools, other interleaved arrangements of magnets 500 and permeable structures 701 are contemplated. For example, FIG. 14 shows an implementation of magnet assembly 700 for implementation in wireline NMR tool 102 of FIG. 4B above.

As shown in FIG. 14, magnet assembly 700 includes a stack of magnets 500 and permeable structures 701 with a magnetization direction 412 that is substantially perpendicular to, and radially separated from, axis 410 of tool 102. Each of magnets 500 of FIG. 14 has a magnetization that is nearly directed in direction 412 (except for natural deviations as described herein) and is corrected by one or more adjacent permeable structures 701 such that the overall magnetization of assembly 700 is in direction 412.

As shown in FIG. 14, the stack of magnets 500 and permeable structures 701 can include an alternating arrangement of permeable structures 701 interleaved with magnets 500 in each of two groups 1402 and 1404 mounted to opposing sides of support structure 1403. As shown, group 1402 may be arranged as a reflection across a center of reflection that coincides with support structure 1403.

Magnets 500 and permeable structures 701 in groups 1402 and 1404 can include variations in size, shape, and/or permeability, as described above in connection with magnets 500 and permeable structures 701 of FIG. 13. Magnets 500 and permeable structures 701 in groups 1402 and 1404 can be variously attached to each other and/or separated by gaps as described above in connection with magnets 500 and permeable structures 701 of FIG. 13. The direction of the magnetization of groups 1402 and 1404 may or may not be reflected about center structure/location 1403 (e.g., may be parallel or antiparallel).

In some examples, the interleaved magnet assemblies of FIGS. 7-14 may form a portion of a magnet assembly that also includes magnet sections without permeable materials.

For example, a magnet assembly 700 as described herein can be formed at the center of a larger magnet assembly in which one or more zones far from the center include only magnet material. As another example, a central section of a larger magnet assembly can be formed only of magnet material with axially outer regions of the larger magnet assembly including one or more magnet assemblies 700 as described herein.

It has been shown that an NMR tool using one or more magnet assemblies 700 configured with permeable structures as in the example of FIGS. 7, 8, 9, 10, 11, 12, 13, and/or 14 can generate a substantial reduction in radial field inhomogeneity and a resulting substantial improvement in downhole NMR operations can be provided.

In accordance with various aspects of the subject disclosure, magnet assemblies are provided for downhole NMR tools that include permeable materials to symmetrize the magnetic field of the assemblies. In this way, magnetic assemblies are provided that can help reduce or eliminate the long tedious methods conventionally involved in correcting for magnetic field deviations and/or asymmetries. In this way, permeable materials can be provided in an assembly to automatically correct for permanent magnet defects so that individual testing and placement of individual magnets to generate a desired field can be reduced or eliminated.

Various examples of aspects of the disclosure are described below as clauses for convenience. These are provided as examples, and do not limit the subject technology.

Clause A. A nuclear magnetic resonance (NMR) tool is provided that includes a magnet assembly that extends along and is symmetric about an axis. The magnet assembly includes a pair of permanent magnets equidistant along the axis from a center of reflection on the axis. The magnet assembly also includes a pair of magnetically permeable structures equidistant along the axis from the center of reflection on the axis.

Clause B. A magnet assembly for a downhole nuclear magnetic resonance (NMR) logging tool is provided, the magnet assembly including an arrangement of permanent magnets. The magnet assembly also includes an arrangement of magnetically permeable structures interleaved with the arrangement of permanent magnets. The arrangement of magnetically permeable structures corrects a direction of a magnetic field of the arrangement of permanent magnets.

Clause C. A drill string assembly having a downhole Nuclear Magnetic Resonance (NMR) tool for wellbore logging in a subterranean formation is provided, the downhole NMR tool including a magnet assembly having a longitudinal axis and configured to produce a magnetic field in a volume in the subterranean formation. The magnet assembly includes a first group of permanent magnets interleaved with a first group of magnetically permeable structures. The magnet assembly also includes a second group of permanent magnets interleaved with a second group of magnetically permeable structures such that the second group of permanent magnets and the second group of magnetically permeable structures are arranged as a reflection of the first group of permanent magnets and the first group of magnetically permeable structures about a center of reflection on the longitudinal axis.

A reference to an element in the singular is not intended to mean one and only one unless specifically so stated, but rather one or more. For example, “a” module may refer to one or more modules. An element proceeded by “a,” “an,” “the,” or “said” does not, without further constraints, preclude the existence of additional same elements.

Headings and subheadings, if any, are used for convenience only and do not limit the invention. The word exemplary is used to mean serving as an example or illustration. To the extent that the term include, have, or the like is used, such term is intended to be inclusive in a manner similar to the term comprise as comprise is interpreted when employed as a transitional word in a claim. Relational terms such as first and second and the like may be used to distinguish one entity or action from another without necessarily requiring or implying any actual such relationship or order between such entities or actions.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A phrase “at least one of” preceding a series of items, with the terms “and” or “or” to separate any of the items, modifies the list as a whole, rather than each member of the list.

The phrase “at least one of” does not require selection of at least one item; rather, the phrase allows a meaning that includes at least one of any one of the items, and/or at least one of any combination of the items, and/or at least one of each of the items. By way of example, each of the phrases “at least one of A, B, and C” or “at least one of A, B, or C” refers to only A, only B, or only C; any combination of A, B, and C; and/or at least one of each of A, B, and C.

It is understood that the specific order or hierarchy of steps, operations, or processes disclosed is an illustration of exemplary approaches. Unless explicitly stated otherwise, it is understood that the specific order or hierarchy of steps, operations, or processes may be performed in different order. Some of the steps, operations, or processes may be performed simultaneously. The accompanying method claims, if any, present elements of the various steps, operations or processes in a sample order, and are not meant to be limited to the specific order or hierarchy presented. These may be performed in serial, linearly, in parallel or in different order. It should be understood that the described instructions, operations, and systems can generally be integrated together in a single software/hardware product or packaged into multiple software/hardware products.

In one aspect, a term coupled or the like may refer to being directly coupled. In another aspect, a term coupled or the like may refer to being indirectly coupled.

Terms such as top, bottom, front, rear, side, horizontal, vertical, and the like refer to an arbitrary frame of reference, rather than to the ordinary gravitational frame of reference. Thus, such a term may extend upwardly, downwardly, diagonally, or horizontally in a gravitational frame of reference.

The disclosure is provided to enable any person skilled in the art to practice the various aspects described herein. In some instances, well-known structures and components are shown in block diagram form in order to avoid obscuring the concepts of the subject technology. The disclosure provides various examples of the subject technology, and the subject technology is not limited to these examples. Various modifications to these aspects will be readily apparent to those skilled in the art, and the principles described herein may be applied to other aspects.

All structural and functional equivalents to the elements of the various aspects described throughout the disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for”.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language of the claims and to encompass all legal equivalents. Notwithstanding, none of the claims are intended to embrace subject matter that fails to satisfy the requirements of the applicable patent law, nor should they be interpreted in such a way.

What is claimed is:

1. A nuclear magnetic resonance (NMR) tool, comprising:
a magnet assembly that extends along and is symmetric about an axis, wherein the magnet assembly comprises:
a pair of permanent magnets equidistant along the axis from a center of reflection on the axis; and
a pair of magnetically permeable structures equidistant along the axis from the center of reflection on the axis.

2. The NMR tool of claim 1, wherein the each of the magnetically permeable structures is disposed axially outward of the pair of permanent magnets.

3. The NMR tool of claim 2, further comprising an additional pair of permanent magnets, axially outward of the pair of permanent magnets and the pair of magnetically permeable structures, wherein each magnetically permeable structure of the pair of magnetically permeable structures is axially interposed between one of the pair of permanent magnets and one of the pair of additional permanent magnets.

4. The NMR tool of claim 3, wherein each of the pair of permanent magnets is formed in contact with one of the pair of magnetically permeable structures.

5. The NMR tool of claim 4, further comprising a gap between each of the pair of magnetically permeable structures and one of the pair of additional permanent magnets.

6. The NMR tool of claim 3, wherein the each of the permanent magnets and each of the magnetically permeable structures has a common axial width and a common radial width.

7. The NMR tool of claim 3, wherein each of the pair of permanent magnets has a first common radial width and each of the pair of additional permanent magnets has a second common radial width that is different from the first common radial width.

8. The NMR tool of claim 3, wherein each of the pair of permanent magnets has a first common axial width and each of the pair of additional permanent magnets has a second common axial width that is different from the first common axial width.

9. The NMR tool of claim 1, wherein each of the pair of permanent magnets has a first common radial width and each of the pair of magnetically permeable structures has a second common radial width that is different from the first common radial width.

10. The NMR tool of claim 1, further comprising:
an antenna assembly; and
an additional magnetically permeable structure that axially separates the antenna assembly from the magnet assembly, wherein the additional magnetically permeable structure has a permeability that is different from a permeability of the pair of magnetically permeable structures.

11. The NMR tool of claim 1, wherein the each of the magnetically permeable structures is disposed axially inward of the pair of permanent magnets.

12. The NMR tool of claim 1, wherein each of the permanent magnets comprises Sm₂Co₁₇ and wherein the each of the pair of magnetically permeable structures has a relative permeability of greater than 10 and a saturation level above one Tesla.

13. A magnet assembly for a downhole nuclear magnetic resonance (NMR) logging tool, the magnet assembly comprising:
an arrangement of permanent magnets; and
an arrangement of magnetically permeable structures interleaved with the arrangement of permanent magnets, wherein the arrangement of magnetically permeable structures corrects a direction of a magnetic field of the arrangement of permanent magnets.

14. The magnet assembly of claim 13, wherein each of the permanent magnets has at least one surface that is in contact with one of the magnetically permeable structures.

15. The magnet assembly of claim 13, wherein each of the magnetically permeable structures in the arrangement of magnetically permeable structures is a cylindrical structure having an inner diameter and an outer diameter, and wherein the outer diameter of at least one of the magnetically permeable structures is different from the outer diameter of at least one other of the magnetically permeable structures.

16. The magnet assembly of claim 13, wherein the tool comprises a longitudinal axis, wherein the magnet assembly has a magnetization direction that is perpendicular to and radially separated from the longitudinal axis, and wherein the arrangement of permanent magnets and the arrangement of magnetically permeable structures each comprise a first portion on a first side of a support structure and a second portion on a second side of the support structure.

17. A drill string assembly comprising a downhole Nuclear Magnetic Resonance (NMR) tool for wellbore logging in a subterranean formation, the downhole NMR tool comprising:
a magnet assembly having a longitudinal axis and configured to produce a magnetic field in a volume in the subterranean formation, the magnet assembly comprising:
a first group of permanent magnets interleaved with a first group of magnetically permeable structures; and
a second group of permanent magnets interleaved with a second group of magnetically permeable structures such that the second group of permanent magnets and the second group of magnetically permeable structures are arranged as a reflection of the first group of permanent magnets and the first group of magnetically permeable structures about a center of reflection on the longitudinal axis.

18. The drill string assembly of claim 17, wherein the downhole NMR tool further comprises:
an antenna configured to:
generate a magnetic field that is substantially perpendicular to a magnetic field formed by the magnet assembly in a zone of interest external to the downhole NMR tool in the subterranean formation, to excite an NMR signal in the zone of interest; and
receive the excited NMR signal from the zone of interest.

19. The drill string assembly of claim 18, further comprising a drill bit, wherein the magnetic assembly has an overall magnetization in a direction that is parallel to the longitudinal axis.

20. A well system comprising:
the drill sting assembly and the drill bit of claim 19;
a drilling rig that supports the drill string assembly; and
a computing subsystem configured to process NMR signals generated in the zone of interest in response to the magnetic field of the magnet assembly and the magnetic field generated by the antenna.
